(19) United States
(12) Patent Application Publication
(10) Pub. No.: US 2026/0251692 A1
(43) Pub. Date: Aug. 27, 2026

(54) SEMICONDUCTOR DEVICE

(71) Applicant: Infineon Technologies Austria AG, Villach (AT)

(72) Inventors: Yuting CHUANG, Hsinchu City (TW); Li Yi PENG, Taichung City (TW)

(21) Appl. No.: 19/062,349

(22) Filed: Feb. 25, 2025

(51) Int. Cl. G01R 31/27; G01R 31/26; H01L 25/07; H10D 80/20

(52) U.S. Cl. CPC G01R 31/275; G01R 31/2601; H10D 80/251; H10W 90/00

(57) ABSTRACT

According to some embodiments, a method comprises generating a threshold voltage measurement for each semiconductor die in a set of semiconductor dies, generating an on current measurement for each semiconductor die in the set of semiconductor dies, selecting a subset of semiconductor dies from the set of semiconductor dies such that each semiconductor die in the subset has a threshold voltage measurement meeting a first threshold and an on current measurement meeting a second threshold, and mounting the subset of semiconductor dies in a semiconductor device package.

### TECHNICAL FIELD

The present disclosure relates to semiconductor devices, for example to gallium nitride (GaN) semiconductor devices and manufacturing methods therefore.

### BACKGROUND

Semiconductor devices are formed on semiconductor wafers and singulated to define semiconductor dies. Due to process variation associated with fabricating the semiconductor wafers, performance metrics for the semiconductor dies vary depending on the region location on the semiconductor wafer where the semiconductor die located.

### SUMMARY

This Summary is provided to introduce a selection of concepts in a simplified form that are further described below in the Detailed Description. This Summary is not intended to identify key factors or essential features of the claimed subject matter, nor is it intended to be used to limit the scope of the claimed subject matter.

According to some embodiments, an integrated circuit device package comprises a first semiconductor die comprising a first transistor having a first gate terminal, a first source terminal, and a first drain terminal, a second semiconductor die comprising a second transistor having a second gate terminal, a second source terminal, and a second drain terminal, and a third semiconductor die comprising a third transistor having a third gate terminal, a third source terminal, and a third drain terminal, wherein the first source terminal, the second source terminal, and the third source terminal are connected in parallel, the first drain terminal, the second drain terminal, and the third drain terminal are connected in parallel, a variation of a first threshold voltage of the first transistor, a second threshold voltage of the second transistor, and a third threshold voltage of the third transistor is less than about 30 percent, and a sum of a first on current of the first transistor, a second on current of the second transistor, and a third on current of the third transistor equals a current rating of the integrated circuit device package.

According to some embodiments, a method comprises generating a threshold voltage measurement for each semiconductor die in a set of semiconductor dies, generating an on current measurement for each semiconductor die in the set of semiconductor dies, selecting a subset of semiconductor dies from the set of semiconductor dies such that each semiconductor die in the subset has a threshold voltage measurement meeting a first threshold and an on current measurement meeting a second threshold, and mounting the subset of semiconductor dies in a semiconductor device package.

According to some embodiments, a method comprises operating each semiconductor die in a set of semiconductor dies mounted to a semiconductor package in parallel, identifying a faulty semiconductor die in the set of semiconductor dies, excluding the faulty semiconductor die from the set of semiconductor dies to generate a modified set of semiconductor dies, and operating each semiconductor die in the modified set of semiconductor dies in parallel.

According to some embodiments, a system comprises means for generating a threshold voltage measurement for each semiconductor die in a set of semiconductor dies, means for generating an on current measurement for each semiconductor die in the set of semiconductor dies, means for selecting a subset of semiconductor dies from the set of semiconductor dies such that each semiconductor die in the subset has a threshold voltage measurement meeting a first threshold and an on current measurement meeting a second threshold, and means for mounting the subset of semiconductor dies in a semiconductor device package.

According to some embodiments, a system comprises means for operating each semiconductor die in a set of semiconductor dies mounted to a semiconductor package in parallel, means for identifying a faulty semiconductor die in the set of semiconductor dies, means for excluding the faulty semiconductor die from the set of semiconductor dies to generate a modified set of semiconductor dies, and means for operating each semiconductor die in the modified set of semiconductor dies in parallel.

To the accomplishment of the foregoing and related ends, the following description and annexed drawings set forth certain illustrative aspects and implementations. These are indicative of but a few of the various ways in which one or more aspects may be employed. Other aspects, advantages, and novel features of the disclosure will become apparent from the following detailed description when considered in conjunction with the annexed drawings.

### DESCRIPTION OF THE DRAWINGS

FIG. 1 is a plan view of a semiconductor wafer, according to some embodiments.

FIG. 2 is a diagram illustrating process layer thickness variation across the semiconductor wafer, in accordance with some embodiments.

FIG. 3 is a diagram illustrating performance sorting, according to some embodiments.

FIG. 4 is a plan view of a semiconductor die, according to some embodiments.

FIG. 5 is a flow chart illustrating an example method for fabricating and operating a semiconductor device, in accordance with some embodiments.

### DETAILED DESCRIPTION

The claimed subject matter is now described with reference to the drawings, wherein like reference numerals are used to refer to like elements throughout. In the following description, for purposes of explanation, numerous specific details are set forth in order to provide a thorough understanding of the claimed subject matter. It may be evident, however, that the claimed subject matter may be practiced without these specific details. In other instances, well-known structures and devices are shown in block diagram form in order to facilitate describing the claimed subject matter.

It is to be understood that the following description of embodiments is not to be taken in a limiting sense. The scope of the present disclosure is not intended to be limited by the embodiments described hereinafter or by the drawings, which are taken to be illustrative only. The drawings are to be regarded as being schematic representations and elements illustrated in the drawings are not necessarily shown to scale. Rather, the various elements are represented such that their function and general purpose become apparent to a person skilled in the art.

All numerical values within the detailed description and the claims herein are modified by “about” or “approximately” the indicated value, and take into account experimental error and variations that would be expected by a person having ordinary skill in the art.

The term “over” and/or “overlying” is not to be construed as meaning only “directly over” and/or “having direct contact with”. Rather, if one element is “over” and/or “overlying” another element (e.g., a region is overlying another region), a further element (e.g., a further region) may be positioned between the two elements (e.g., a further region may be positioned between a first region and a second region if the first region is “over” and/or “overlying” the second region). Further, if a first element is “over” and/or “overlying” a second element, at least some of the first element may be vertically coincident with the second element, such that a vertical line may intersect the first element and the second element.

The semiconductor substrate or body may extend along a main extension plane. The term “horizontal” as used in this specification intends to describe an orientation substantially parallel to said main extension plane. A first or main horizontal side of the semiconductor substrate or body may run substantially parallel to horizontal directions or may have surface sections that enclose an angle of at most 8° (or at most 6° or at most) 4° with the main extension plane. The first or main horizontal side can be for instance the surface of a wafer or a die. Sometimes, the horizontal direction is also referred to as lateral direction.

The term “vertical” as used in this specification intends to describe an orientation which is substantially arranged perpendicular to the horizontal direction, (e.g., parallel to the normal direction of the first side of the semiconductor substrate or body or parallel to the normal direction of a surface section of the first side of the semiconductor substrate or body).

In accordance with the present disclosure, a semiconductor device and a method of manufacturing the semiconductor device are provided. The embodiments described herein may be combined in any way.

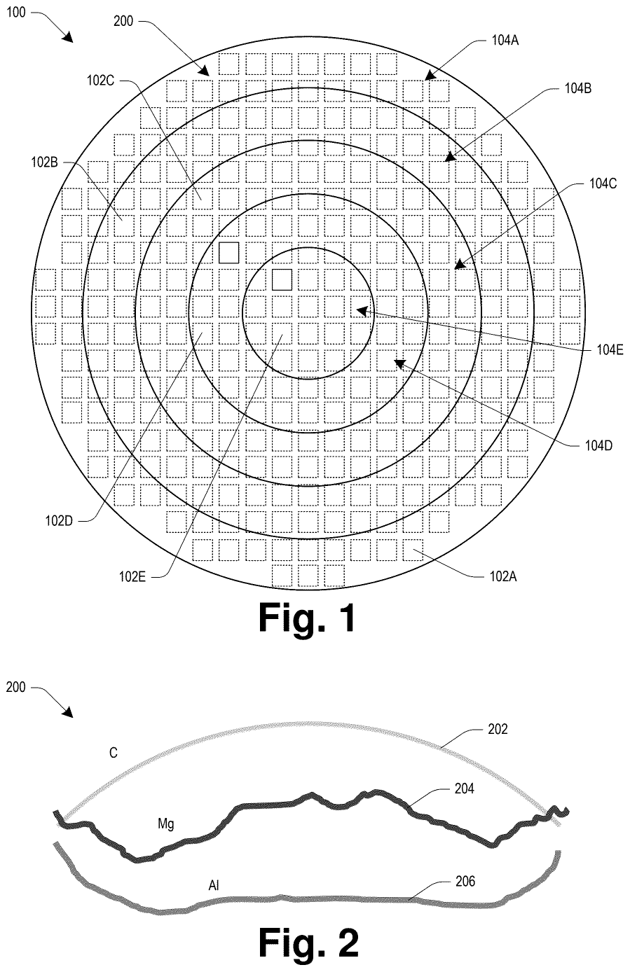

FIG. 1 is a plan view of a semiconductor wafer 100, according to some embodiments. In some embodiments, the semiconductor wafer 100 is subjected to a series of process operations to define semiconductor dies 102. The number and arrangement of the dies 102 may vary. The process operations include forming process layers on the semiconductor wafer 100, patterning the process layers using photolithography and etching processes, performing planarizing processes on selected process layers, and other processes. The process operations produce different results depending on the region 104A, 104B, 104C, 104D, 104E of the semiconductor wafer 100. For example, the die 102A is in an edge region 104A, the die 102E is in the center region 104E, and the dies 102B, 102C, 102D are in intermediate regions 104B, 104C, 104D. In one example, process layer thicknesses can vary depending on the region 104A, 104B, 104C, 104D, 104E.

In some embodiments, each semiconductor die 102 may comprise a single transistor, such as a gallium nitride (GaN) based transistor. The transistor may include a gate terminal, a source terminal, and a drain terminal. The transistors in the semiconductor dies 102 may be used for high power switching applications, such as voltage regulation, motor control, industrial control, inverters, electric vehicles, or some other application.

FIG. 2 is a diagram 200 illustrating process layer dopant variation across the semiconductor wafer 100, in accordance with some embodiments. A profile curve 202 illustrates carbon (C) dopant variation, a profile curve 204 illustrates magnesium (MG) dopant variation, and a profile curve 206 illustrates aluminum (Al) dopant variation. The process layer dopant variation causes performance variation in the semiconductor dies 102.

Due to the process variation in the regions 104A, 104B, 104C, 104D, 104E, the performance metrics associated with the dies 102 vary. Performance metrics include threshold voltage (V_{TH}), saturation on-current (I_{DSAT}), drain-to-source on-resistance (R_{ON}), source leakage current (I_{GSS}), drain leakage current (I_{DOFF}), or other suitable performance metrics. Typically performance of the dies 102 is higher in the center region 104E and degrades in the direction of the edge region 102A.

Typically, different designs are employed for different performance grades for the transistor devices, resulting in significant engineering costs and development time. For example, if individual dies 102 were used to fulfill orders for high performance grade transistors, only a fraction of the dies 102 on the semiconductor wafer 100 would meet the performance thresholds. However, in accordance with the techniques described herein, multiple semiconductor dies 102 are connected in parallel and packaged in a single semiconductor package, where the performance grade is assigned for the semiconductor device package rather than the individual semiconductor dies 102. Thus, semiconductor dies 102 may be sorted and selected for inclusion into different semiconductor packages depending on the desired grade. Different performance thresholds may be used to define the different performance grades for the semiconductor packages for fulfilling orders. In this manner, the yield of the semiconductor dies 102 for fulfilling orders may be increased, fabrication costs may be reduced, and inventory levels may be decreased. Using multiple semiconductor dies 102 in a single semiconductor device package also improves fault tolerance, as the failure of one of the semiconductor dies 102 does not result in complete failure.

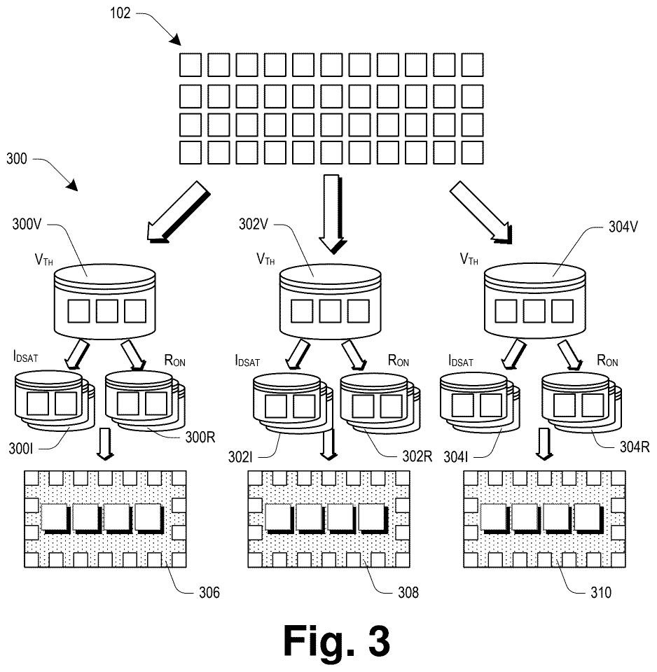

FIG. 3 is a diagram illustrating sorting of the semiconductor dies 102 based on performance metrics. In some embodiments, a first level sort is conducted based on threshold voltage (V_{TH}) into bins 300V, 302V, 304V. A pre-defined range of threshold voltages (V_{TH}) for the transistors on the semiconductor dies 102 is defined for each voltage bin 300V, 302V, 304V. Thus, the semiconductor dies 102 in each voltage bin 300V, 302V, 304V have similar threshold voltages (V_{TH}), and when multiple semiconductor dies 102 are connected in parallel, the threshold voltage (V_{TH}) of the composite device are also within the range for the associated voltage bin 300V, 302V, 304V.

Second level sorts are conducted to sort the semiconductor dies 102 based on saturation on-current (I_{DSAT}) and drain-to-source on-resistance (R_{ON}) into current bins 3001, 3021, 3041 and resistance bins 300R, 302R, 304R. Each semiconductor die 102 in a given threshold voltage bin 300V, 302V, 304V will be sorted into one of the current bins 3001, 3021, 3041 and one of the resistance bins 300R, 302R, 304R.

After sorting the semiconductor dies 102, semiconductor dies 102 are selected based on the required performance metrics and are mounted in semiconductor device packages 306, 308, 310. For example, the semiconductor device package 306 has a composite threshold voltage (V_{TH}) corresponding to the range of the associated voltage bin 300V. In some embodiments, a threshold voltage rating of the semiconductor device package 306 may be the maximum threshold voltage of the semiconductor dies 102 so that all turn on if a voltage matching the threshold voltage rating is applied to the semiconductor device package 306.

Semiconductor dies 102 from the current bins 3001 and resistance bins 300R can be selected for the semiconductor device package 306 to meet the composite saturation on-current (I_{DSAT}) and on-resistance (R_{ON}) performance thresholds for the performance grade needed. For a composite device, the saturation on-current (I_{DSAT}) is cumulative for the selected semiconductor dies 102 and the drain-to-source on-resistance (R_{ON}) is based on the reciprocal sum:

$$\frac{1}{{R}_{T}} = \frac{1}{{R}_{1}} + \frac{1}{{R}_{2}} + \frac{1}{{R}_{3}} + …$$

In this manner, semiconductor dies 102 from different regions 104A, 104B, 104C, 104D, 104E of the semiconductor wafer 100 can be packaged together to meet the performance grade, increasing the yield of the semiconductor dies 102 and reducing inventory levels. Rather than fabricating different designs for different performance grades, the semiconductor device packages 306, 308, 310 can be configured to meet different performance grades based on matching the semiconductor dies 102.

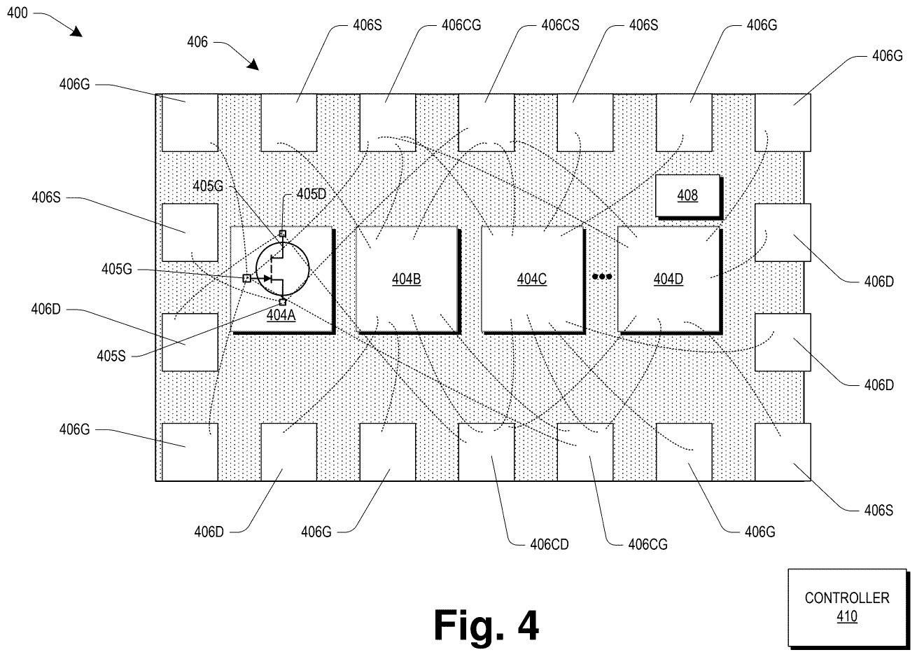

FIG. 4 is a plan view of a semiconductor device package 400, according to some embodiments. The semiconductor device package 400 may be one of the semiconductor device packages 306, 308, 310 illustrated in FIG. 3. In some embodiments, the semiconductor device package 400 comprises multiple semiconductor dies 404A, 404B, 404C, 404D (i.e., the semiconductor dies 102 in FIG. 1 or FIG. 3) and external pads 406 connected to the dies. The number and arrangement of semiconductor dies 404A, 404B, 404C, 404D may vary. In some embodiments, the semiconductor dies 404A, 404B, 404C, 404D each comprises a single transistor comprising a source terminal 405S, a drain terminal 405D, and a gate terminal 405G. The source terminal 405S, drain terminal 405D, and gate terminal 405G may comprise one or more external contact pads on top side or the back side of the semiconductor die 404A, 404B, 404C, 404D.

The semiconductor dies 404A, 404B, 404C, 404D are connected in parallel by embedded interconnect structures or wire bonds in the semiconductor device package 400. The semiconductor dies 404A, 404B, 404C, 404D may include surface contacts or bottom contacts connected to the external pads 406. The external pads 406 are connected to the semiconductor device package 400 to allow external access to the semiconductor dies 404A, 404B, 404C, 404D. The number, type, and arrangement of external pads 406 may vary. Example external pads 406 include external gate pads 406G, external source pads 406S, or external drain pads 406D connected to individual semiconductor dies 404A, 404B, 404C, 404D or common external gate pads 406CG, a common external source pad 406CS, and a common external drain pad 404CD connected to all of the semiconductor dies 404A, 404B, 404C, 404D.

The external pads 406 allow flexibility for operating the semiconductor dies 404A, 404B, 404C, 404D in the semiconductor device package 400. For example, to provide fault tolerance, a failed semiconductor die may be bypassed by accessing the semiconductor device package 400 using different external pads 406. For example, if all the semiconductor dies 404A, 404B, 404C, 404D in the semiconductor device package 400 are operable, the common external pads 406CG, 406CS, 406CD may be used to access the semiconductor dies 404A, 404B, 404C, 404D in parallel. If one of the semiconductor dies 404A, 404B, 404C, 404D were to fail, one of more of the individual external pads 406G, 406D, 406D may be used to access the non-faulted semiconductor dies 404A, 404B, 404C, 404D individually. For example, a failed device may be bypassed by enabling the external gate pads 406G for the non-faulted semiconductor dies 404A, 404B, 404C, 404D while still using the common source pad 406CS and common drain pad 406CD.

In some embodiments, faulty semiconductor dies 404A, 404B, 404C, 404D may be identified by detecting a change in one or more performance parameters of the semiconductor device package 400. For example, the threshold voltage (V_{TH}) of the semiconductor device package 400 decreases and the source leakage current (I_{GSS}) increases in step-wise fashions as the number of faulty semiconductor dies 404A, 404B, 404C, 404D increases.

In some embodiments, a detection die 408 is mounted in the semiconductor device package 400 to measure the threshold voltage (V_{TH}) or the source leakage current (I_{GSS}) to report faulty semiconductor dies 404A, 404B, 404C, 404D at the system level. Alternatively, the system in which the semiconductor device package 400 is installed may include a controller 410 comprising detection circuitry to detect the faulty semiconductor dies 404A, 404B, 404C, 404D or to control which external pads 406 are used for accessing the semiconductor dies 404A, 404B, 404C, 404D.

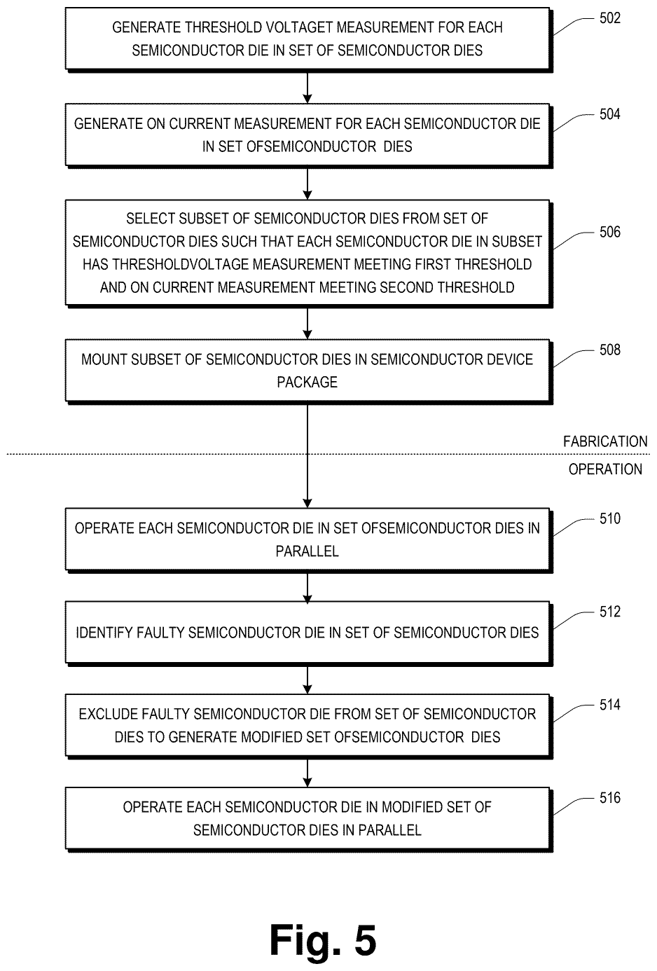

FIG. 5 is a flow chart illustrating an example method 500 for fabricating and operating a semiconductor device, in accordance with some embodiments. At 502 a threshold voltage measurement for each semiconductor die 102 in a set of semiconductor dies is generated. At 504, an on current measurement is generated for each semiconductor die 102 in the set of semiconductor dies. At 506, a subset of semiconductor dies 102 from the set of semiconductor dies is selected such that each semiconductor die 102 in the subset has a threshold voltage measurement meeting a first threshold and on current measurement meeting a second threshold. At 508, the subset of semiconductor dies 102 is mounted in a semiconductor device package 400. Method steps 502, 504, 506, and 508 represent fabrication steps.

At 510, operating each semiconductor die 404A, 404B, 404C in the set of semiconductor dies is operated in parallel. At 512, a faulty semiconductor die in the set of semiconductor dies is identified. At 514, the faulty semiconductor die is excluded from the set of semiconductor dies to generate a modified set of semiconductor dies. At 516, each semiconductor die in the modified set of semiconductor dies is operated in parallel. Method steps 510, 512, 514, and 516 represent operation steps.

It may be appreciated that combinations of one or more embodiments described herein, including combinations of embodiments described with respect to different figures, are contemplated herein.

According to some embodiments, an integrated circuit device package comprises a first semiconductor die comprising a first transistor having a first gate terminal, a first source terminal, and a first drain terminal, a second semiconductor die comprising a second transistor having a second gate terminal, a second source terminal, and a second drain terminal, and a third semiconductor die comprising a third transistor having a third gate terminal, a third source terminal, and a third drain terminal, wherein the first source terminal, the second source terminal, and the third source terminal are connected in parallel, the first drain terminal, the second drain terminal, and the third drain terminal are connected in parallel, a variation of a first threshold voltage of the first transistor, a second threshold voltage of the second transistor, and a third threshold voltage of the third transistor is less than about 30 percent, and a sum of a first on current of the first transistor, a second on current of the second transistor, and a third on current of the third transistor equals a current rating of the integrated circuit device package.

According to some embodiments, a resistance rating of the integrated circuit device package is based on a reciprocal sum of a first on resistance of the first transistor, a second on resistance of the second transistor, and a third on resistance of the third transistor.

According to some embodiments, the integrated circuit device package comprises a first external gate pad connected to the first gate terminal, a second external gate pad connected to the second gate terminal, and a third external gate pad connected to the third gate terminal.

According to some embodiments, the integrated circuit device package comprises a first external pad connected to the first drain terminal, the second drain terminal, and the third drain terminal and a second external pad connected to the first source terminal, the second source terminal, and the third source terminal.

According to some embodiments, a method comprises generating a threshold voltage measurement for each semiconductor die in a set of semiconductor dies, generating an on current measurement for each semiconductor die in the set of semiconductor dies, selecting a subset of semiconductor dies from the set of semiconductor dies such that each semiconductor die in the subset has a threshold voltage measurement meeting a first threshold and an on current measurement meeting a second threshold, and mounting the subset of semiconductor dies in a semiconductor device package.

According to some embodiments, each semiconductor die in the subset comprises a transistor and mounting the subset of semiconductor dies in the semiconductor package comprises connecting the transistors of the semiconductor dies in the subset in parallel.

According to some embodiments, each semiconductor die in the subset comprises a transistor having a source terminal and a drain terminal and mounting the subset of semiconductor dies in the semiconductor package comprises connecting the source terminals of the transistors of the semiconductor dies in the subset in parallel and connecting the drain terminals of the transistors of the semiconductor dies in the subset in parallel.

According to some embodiments, mounting the subset of semiconductor dies in the semiconductor package comprises connecting the source terminals of the transistors of the semiconductor dies in the subset to an external source pad and connecting the drain terminals of the transistors of the semiconductor dies in the subset to an external drain pad.

According to some embodiments, each semiconductor die in the subset comprises a transistor having a gate terminal and mounting the subset of semiconductor dies in the semiconductor package comprises connecting the gate terminals of the transistors of the semiconductor dies in the subset to separate external gate pads.

According to some embodiments, selecting the subset of semiconductor dies from the set of semiconductor dies comprises selecting the subset of semiconductor dies such that each semiconductor die in the subset has an on resistance measurement meeting a third threshold.

According to some embodiments, the method comprises determining an on resistance rating of the semiconductor device package as a function of the on resistance measurements for each semiconductor die in the subset of semiconductor dies.

According to some embodiments, the method comprises determining an on current rating of the semiconductor device package as a function of the on current measurements for each semiconductor die in the subset of semiconductor dies.

According to some embodiments, the method comprises determining a threshold voltage rating of the semiconductor device package as a function of the threshold voltage measurements for each semiconductor die in the subset of semiconductor dies.

According to some embodiments, the method comprises identifying a faulty semiconductor die in the subset of semiconductor dies after mounting the subset of semiconductor dies in the semiconductor device package and programming a fault flag for the faulty semiconductor die in the semiconductor device package.

According to some embodiments, the method comprises operating each semiconductor die in the subset of semiconductor dies in parallel, identifying a faulty semiconductor die in the subset of semiconductor dies after mounting the subset of semiconductor dies in the semiconductor device package, excluding the faulty semiconductor die from the subset of semiconductor dies to generate a modified subset of semiconductor dies, and operating each semiconductor die in the modified subset of semiconductor dies in parallel.

According to some embodiments, a method comprises operating each semiconductor die in a set of semiconductor dies mounted to a semiconductor package in parallel, identifying a faulty semiconductor die in the set of semiconductor dies, excluding the faulty semiconductor die from the set of semiconductor dies to generate a modified set of semiconductor dies, and operating each semiconductor die in the modified set of semiconductor dies in parallel.

According to some embodiments, each semiconductor die in the set of semiconductor dies comprises a transistor having a source terminal and a drain terminal and the method comprises connecting the source terminals of the transistors of the semiconductor dies in the set of semiconductor dies in parallel and connecting the drain terminals of the transistors of the semiconductor dies in the set of semiconductor dies in parallel.

According to some embodiments, each semiconductor die in the set of semiconductor dies comprises a transistor having a gate terminal connected to a separate external gate pad and operating each semiconductor die in the set of semiconductor dies in parallel comprises applying a gate control signal to each of the separate external gate pads.

According to some embodiments, operating each semiconductor die in the modified set of semiconductor dies in parallel comprises applying the gate control signal to each of the separate external gate pads except the external gate pad connected to the gate terminal of the transistor of the faulty semiconductor die.

According to some embodiments, identifying the faulty semiconductor die comprises identifying a change in leakage current of a transistor of the faulty semiconductor die.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

Any aspect or design described herein as an “example” is not necessarily to be construed as advantageous over other aspects or designs. Rather, use of the word “example” is intended to present one possible aspect and/or implementation that may pertain to the techniques presented herein. Such examples are not necessary for such techniques or intended to be limiting. Various embodiments of such techniques may include such an example, alone or in combination with other features, and/or may vary and/or omit the illustrated example.

As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims may generally be construed to mean “one or more” unless specified otherwise or clear from context to be directed to a singular form. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others skilled in the art based upon a reading and understanding of this specification and the annexed drawings. The disclosure includes all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure which performs the function in the herein illustrated example implementations of the disclosure. In addition, while a particular feature of the disclosure may have been disclosed with respect to only one of several implementations, such feature may be combined with one or more other features of the other implementations as may be desired and advantageous for any given or particular application. Furthermore, to the extent that the terms “includes”, “having”, “has”, “with”, or variants thereof are used in either the detailed description or the claims, such terms are intended to be inclusive in a manner similar to the term “comprising.”

While the subject matter has been described with reference to illustrative embodiments, this description is not intended to be construed in a limiting sense. Various modifications and combinations of the illustrative embodiments, as well as other embodiments of the present disclosure, will be apparent to persons skilled in the art upon reference to the description. It is therefore intended that the appended claims encompass any such modifications or embodiments.

What is claimed is:

1. An integrated circuit device package, comprising:
a first semiconductor die comprising a first transistor having a first gate terminal, a first source terminal, and a first drain terminal;
a second semiconductor die comprising a second transistor having a second gate terminal, a second source terminal, and a second drain terminal; and
a third semiconductor die comprising a third transistor having a third gate terminal, a third source terminal, and a third drain terminal, wherein:
the first source terminal, the second source terminal, and the third source terminal are connected in parallel;
the first drain terminal, the second drain terminal, and the third drain terminal are connected in parallel;
a variation of a first threshold voltage of the first transistor, a second threshold voltage of the second transistor, and a third threshold voltage of the third transistor is less than about 30 percent; and
a sum of a first on current of the first transistor, a second on current of the second transistor, and a third on current of the third transistor equals a current rating of the integrated circuit device package.

2. The integrated circuit device package of claim 1, wherein:
a resistance rating of the integrated circuit device package is based on a reciprocal sum of a first on resistance of the first transistor, a second on resistance of the second transistor, and a third on resistance of the third transistor.

3. The integrated circuit device package of claim 1, comprising:
a first external gate pad connected to the first gate terminal;
a second external gate pad connected to the second gate terminal; and
a third external gate pad connected to the third gate terminal.

4. The integrated circuit device package of claim 1, comprising:
a first external pad connected to the first drain terminal, the second drain terminal, and the third drain terminal; and
a second external pad connected to the first source terminal, the second source terminal, and the third source terminal.

5. A method, comprising:
generating a threshold voltage measurement for each semiconductor die in a set of semiconductor dies;
generating an on current measurement for each semiconductor die in the set of semiconductor dies;
selecting a subset of semiconductor dies from the set of semiconductor dies such that each semiconductor die in the subset has a threshold voltage measurement meeting a first threshold and an on current measurement meeting a second threshold; and
mounting the subset of semiconductor dies in a semiconductor device package.

6. The method of claim 5, wherein:
each semiconductor die in the subset comprises a transistor; and
mounting the subset of semiconductor dies in the semiconductor package comprises:
connecting the transistors of the semiconductor dies in the subset in parallel.

7. The method of claim 5, wherein:
each semiconductor die in the subset comprises a transistor having a source terminal and a drain terminal; and
mounting the subset of semiconductor dies in the semiconductor package comprises:
connecting the source terminals of the transistors of the semiconductor dies in the subset in parallel; and
connecting the drain terminals of the transistors of the semiconductor dies in the subset in parallel.

8. The method of claim 7, wherein:
mounting the subset of semiconductor dies in the semiconductor package comprises:
connecting the source terminals of the transistors of the semiconductor dies in the subset to an external source pad; and
connecting the drain terminals of the transistors of the semiconductor dies in the subset to an external drain pad.

9. The method of claim 5, wherein:
each semiconductor die in the subset comprises a transistor having a gate terminal; and
mounting the subset of semiconductor dies in the semiconductor package comprises:
connecting the gate terminals of the transistors of the semiconductor dies in the subset to separate external gate pads.

10. The method of claim 5, wherein:
selecting the subset of semiconductor dies from the set of semiconductor dies comprises selecting the subset of semiconductor dies such that each semiconductor die in the subset has an on resistance measurement meeting a third threshold.

11. The method of claim 10, comprising:
determining an on resistance rating of the semiconductor device package as a function of the on resistance measurements for each semiconductor die in the subset of semiconductor dies.

12. The method of claim 5, comprising:
determining an on current rating of the semiconductor device package as a function of the on current measurements for each semiconductor die in the subset of semiconductor dies.

13. The method of claim 5, comprising:
determining a threshold voltage rating of the semiconductor device package as a function of the threshold voltage measurements for each semiconductor die in the subset of semiconductor dies.

14. The method of claim 5, comprising:
identifying a faulty semiconductor die in the subset of semiconductor dies after mounting the subset of semiconductor dies in the semiconductor device package; and
programming a fault flag for the faulty semiconductor die in the semiconductor device package.

15. The method of claim 5, comprising:
operating each semiconductor die in the subset of semiconductor dies in parallel;
identifying a faulty semiconductor die in the subset of semiconductor dies after mounting the subset of semiconductor dies in the semiconductor device package;
excluding the faulty semiconductor die from the subset of semiconductor dies to generate a modified subset of semiconductor dies; and
operating each semiconductor die in the modified subset of semiconductor dies in parallel.

16. A method, comprising:
operating each semiconductor die in a set of semiconductor dies mounted to a semiconductor package in parallel;
identifying a faulty semiconductor die in the set of semiconductor dies;
excluding the faulty semiconductor die from the set of semiconductor dies to generate a modified set of semiconductor dies; and
operating each semiconductor die in the modified set of semiconductor dies in parallel.

17. The method of claim 16, wherein:
each semiconductor die in the set of semiconductor dies comprises a transistor having a source terminal and a drain terminal; and
the method comprises:
connecting the source terminals of the transistors of the semiconductor dies in the set of semiconductor dies in parallel; and
connecting the drain terminals of the transistors of the semiconductor dies in the set of semiconductor dies in parallel.

18. The method of claim 16, wherein:
each semiconductor die in the set of semiconductor dies comprises a transistor having a gate terminal connected to a separate external gate pad; and
operating each semiconductor die in the set of semiconductor dies in parallel comprises:
applying a gate control signal to each of the separate external gate pads.

19. The method of claim 18, wherein:
operating each semiconductor die in the modified set of semiconductor dies in parallel comprises:
applying the gate control signal to each of the separate external gate pads except the external gate pad connected to the gate terminal of the transistor of the faulty semiconductor die.

20. The method of claim 16, wherein:
identifying the faulty semiconductor die comprises:
identifying a change in leakage current of a transistor of the faulty semiconductor die.
